(19) United States
(12) Patent Application Publication
(10) Pub. No.: US 2021/0149594 A1
(43) Pub. Date: May 20, 2021

(54) SOLID-STATE DEVICES TO REDUCE LATENCY BY EMPLOYING INSTRUCTION TIME SLICING TO NON-VOLATILE MEMORY (NVM) SETS MAPPED TO INDEPENDENTLY PROGRAMMABLE NVM PLANES

(71) Applicant: Microsoft Technology Licensing, LLC, Redmond, WA (US)

(72) Inventor: Monish Shantilal SHAH, Sammamish, WA (US)

(21) Appl. No.: 16/687,792

(22) Filed: Nov. 19, 2019

(51) Int. Cl. G06F 3/06

(52) U.S. Cl. CPC G06F 3/0659; G06F 3/0679; G06F 3/0611

(57) ABSTRACT

Solid-state devices (SSDs) reduce latency by employing instruction time slicing to non-volatile memory (NVM) sets mapped to independently programmable NVM planes. Memory cells in a NVM die are divided into planes that each have enough storage capacity for a storage space (NVM set) of an application executing in an electronic device. To allow separate processes to access NVM sets in the same NVM die with reduced tail latency, a SSD employs a SSD control circuit determining instruction-type time slices in which specific types of instructions are generated, and NVM dies capable of concurrently accessing independent memory locations of respective planes. The SSD control circuit determines a write instruction-type time slice and generates a write instruction. A NVM die, in response to the write instruction, writes to a first page in a first plane indicated in the write instruction, and concurrently writes to a second page in a second plane.

### FIELD OF THE DISCLOSURE

The technology of the disclosure relates generally to non-volatile memory solid-state devices, and more particularly to accessing memory in planes of a non-volatile memory die in a solid-state device.

### BACKGROUND

A solid-state device (SSD) is a non-volatile semiconductor-based data storage device providing long term data storage similar to a rotating magnetic disk drive (“disk drive”). SSDs can be employed in many devices for which a disk drive is not well suited, such as laptops, tablets, and other mobile devices. The memory space in a storage device is used to store data for applications that execute in a processing circuit. The memory space can be logically partitioned into, for example, a “C:/drive” and a “D:/ drive” accessed by different processes. The storage space of a first application can be mapped to one logical partition (e.g., C:/ drive) while the storage space of another application is mapped to the other partition (e.g., D:/ drive). However, both applications will occasionally attempt to access their respective memories at the same time. An application accesses memory to write, read, or erase data. In this case, memory instructions of both processes are attempting to access memory locations within the same physical device, but the storage device may only access one memory location at a time. Thus, the respective memory accesses are handled sequentially. As a result, a later arriving memory instruction will not start until the storage device has completed an earlier memory instruction, causing a small percentage of memory instructions to take much longer than normal to complete. For example, a write instruction followed by a read instruction, which normally completes in much less time than a write instruction, will be delayed until the program instruction is complete. This type of occasional increase in latency in disk drives and SSDs is known as tail latency.

Internally, a SSD includes a controller and a plurality of non-volatile memory (NVM) dies coupled to the controller via channels. Data is stored in the NVM dies. A NVM die may be implemented with NAND Flash memory, but other NVM types are known and new types continue to be developed. The total memory capacity of a SSD depends on the capacity and number of the NVM dies therein. The memory space can be logically partitioned and allocated for mapping storage spaces of applications or processes. One way to partition a SSD is to create “NVM sets,” which can be mapped to a number of NVM dies within a SSD having the desired capacity. More information regarding NVM sets may be found in the “NVM Express™ Base Specification,” Revision 1.4 released Jun. 10, 2019. Conventional NVM dies handle memory accesses sequentially, or non-sequentially with certain addressing limitations. As a result, instructions arriving to a NVM die at the same time may conflict or interfere with each other, causing the latency problem discussed above. Therefore, the minimum size of a NVM set is generally set to a single NVM die, because if multiple NVM sets are implemented within a single NVM die, they will suffer from tail latency.

As fabrication technologies improve, the storage capacity of NVM dies continues to increase. Thus, if the minimum size of a NVM set corresponds to the size of a NVM die, the size of the NVM set also increases. However, the maximum storage space needed for some applications remains constant. If the storage capacity of the smallest available NVM die becomes twice as large as the capacity of the NVM set needed for an application, for example, half the storage capacity of the NVM die would go unused. If multiple NVM sets are mapped to the same NVM die, those processes could all incur tail latency problems. It would be beneficial if the size of a NVM set could be made smaller than the capacity of a NVM die without incurring long tail latency.

### SUMMARY

Exemplary aspects disclosed herein include solid-state devices (SSDs) to reduce latency by employing instruction time slicing to non-volatile memory (NVM) sets mapped to independently programmable NVM planes. Memory cells in a NVM die disclosed herein are logically divided into two or more planes that each have enough storage capacity for a storage space (NVM set) of an application executing in an electronic device. To allow separate processes to access NVM sets in the same NVM die with reduced tail latency, a SSD disclosed herein employs a SSD control circuit determining instruction-type time slices in which specific types of instructions are generated, and NVM dies capable of concurrently accessing independent memory locations of respective planes. The instructions executed in a NVM die include an erase instruction, a read instruction, and a program instruction (referred to herein as a “write instruction”).

In particular, the SSD control circuit determines a write instruction-type time slice and generates a write instruction. A NVM die, in response to the write instruction, writes to a first page in a first plane indicated in the write instruction, and concurrently writes to a second page in a second plane. The NVM die may write data in the second page in the second plane in response to receiving a second write instruction during the write instruction-type time slice, or in response to the first write instruction. A location of the first page within the first plane is independent from a location of the second page within the second plane. The SSD control circuit also determines instruction-type time slices for read and erase instructions during which only those types of instructions are generated. A SSD employing both a SSD control circuit determining instruction-type time slices, and a plurality of NVM dies concurrently writing to independent pages of different planes, can reduce tail latency of two or more processes having NVM sets mapped to planes of a NVM die.

In one aspect, a SSD circuit including a SSD control circuit coupled to a channel is disclosed. The SSD control circuit is configured to determine instruction-type time slices during each of which only instructions of a type corresponding to a respective instruction-type time slice are generated on the channel and, in a write instruction-type time slice among the determined instruction-type time slices, during which only write type instructions are generated on the channel, generate, on the channel, a write instruction. The SSD circuit also includes a NVM circuit coupled to the channel. The NVM circuit includes a first plane comprising a first plurality of blocks each formed of pages, and a second plane comprising a second plurality of blocks each formed of pages. The NVM circuit is configured to, in response to the write instruction generated on the channel indicating a first page in the first plane, write to the first page in the first plane and, concurrently with writing to the first page in the first plane, write to a second page in the second plane, an address of the second page in the second plane independent of an address of the first page in the first plane.

In another aspect, a NVM circuit is disclosed. The NVM circuit includes a first plane comprising a first plurality of blocks each formed of pages, a second plane comprising a second plurality of blocks each formed of pages, and a control circuit. The control circuit is configured to receive a first instruction indicating a first page in the first plane, in response to receiving the first instruction, write to the first page in the first plane, and concurrently with writing to the first page in the first plane, write to a second page in the second plane, an address of the second page in the second plane independent of an address of the first page in the first plane.

In another aspect, a SSD control circuit is disclosed. The SSD control circuit is configured to determine instruction-type time slices during each of which only instructions of a type corresponding to a respective instruction-type time slice are generated on a channel. The SSD control circuit is further configured to, during a write instruction-type time slice of the determined instruction-type time slices during which only write type instructions are generated on the channel, generate, on the channel, a write instruction, the write instruction indicating a first page in a plane of a NVM circuit, and indicating a second page of a second plane of the NVM circuit, an address of the first page independent of an address of the second page.

In another aspect, a method performed in a SSD circuit is disclosed. The method includes, in a SSD control circuit in the SSD circuit, determining instruction-type time slices during each of which only instructions of a type corresponding to a respective instruction-type time slice are generated on a channel, and during a write instruction-type time slice of the determined instruction-type time slices, during which only write type instructions are generated on the channel, generating, on the channel, a write instruction. The method further includes, in a NVM circuit coupled to the channel, in response to the write instruction generated on the channel during the write instruction-type time slice, writing to a first page in a first plane of the NVM circuit, and concurrently with writing to the first page in the first plane, writing to a second page in a second plane of the NVM circuit, an address of the second page in the second plane independent of an address of the first page in the first plane.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary solid-state device (SSD) including a SSD control circuit that determines instruction-type time slices and a plurality of non-volatile memory (NVM) dies that concurrently access independent memory locations of pages of a NVM die in one example of a logical memory partitions (NVM sets) configuration;

FIG. 2 is a schematic diagram of the exemplary SSD of FIG. 1 illustrating another example of a configuration of NVM sets;

FIG. 3 is a schematic diagram illustrating memory organization of planes in NVM dies in the SSD of FIGS. 1 and 2, where each of the planes includes a plurality of blocks each formed of pages of NVM cells accessed by the SSD control circuit;

FIG. 4 is a graphical representation of memory access times plotted along the X-axis and frequencies of occurrence of such latencies plotted along the Y-axis in a SSD configured with NVM sets mapped to individual planes of NVM dies that do not include inventive aspects disclosed herein;

FIG. 5 is a timing diagram illustrating exemplary instruction-type time slices during which only instructions of a type corresponding to the instruction-type time slice are generated by the SSD control circuit in FIGS. 1 and 2, the instructions being concurrently executed in the NVM dies of FIGS. 1 and 2;

FIG. 6 is a flowchart of an exemplary process performed in the SSD of FIGS. 1 and 2 in which a SSD control circuit determines instruction-type time slices as illustrated in FIG. 5 and generates an instruction corresponding to the instruction-type time slice, and the NVM die concurrently writes to independent pages in respective planes in response to generated instructions;

FIG. 7 is a schematic diagram of a NVM die in the SSD in FIGS. 1 and 2 configured to perform aspects of the process illustrated in the flowchart in FIG. 6 in which independent pages in different planes of the NVM die can be concurrently written;

FIG. 8 is a schematic diagram of a SSD control circuit of the SSD in FIGS. 1 and 2 configured to perform aspects of the process illustrated in FIG. 6 in which instruction-type time slices are determined and instructions of a type corresponding to an instruction-type time slice are generated; and

FIG. 9 is a block diagram of an exemplary processor-based system including the exemplary SSD of FIGS. 1 and 2 including the NVM die of FIG. 7 and the SSD control circuit of FIG. 8.

### DETAILED DESCRIPTION

Exemplary aspects disclosed herein include solid-state devices (SSDs) to reduce latency by employing instruction time slicing to non-volatile memory (NVM) sets mapped to independently programmable NVM planes. Memory cells in a NVM die disclosed herein are logically divided into two or more planes that each have enough storage capacity for a storage space (NVM set) of an application that executing in an electronic device. To allow separate processes to access NVM sets in the same NVM die with reduced tail latency, a SSD disclosed herein employs a SSD control circuit determining instruction-type time slices in which specific types of instructions are generated, and NVM dies capable of concurrently accessing independent memory locations of respective planes. The instructions executed in a NVM die include an erase instruction, a read instruction, and a program instruction (referred to herein as a “write instruction”).

In particular, the SSD control circuit determines a write instruction-type time slice and generates a write instruction. A NVM die, in response to the write instruction, writes to a first page in a first plane indicated in the write instruction, and concurrently writes to a second page in a second plane. The NVM die may write data in the second page in the second plane in response to receiving a second write instruction during the write instruction-type time slice, or in response to the first write instruction. A location of the first page within the first plane is independent from a location of the second page within the second plane. The SSD control circuit also determines instruction-type time slices for read and erase instructions during which only those types of instructions are generated. A SSD employing both a SSD control circuit determining instruction-type time slices, and a plurality of NVM dies concurrently writing to independent pages of different planes, can reduce tail latency of two or more processes having NVM sets mapped to planes of a NVM die.

In the Figures described herein, common features among different Figures are commonly labeled.

Some amount of memory is needed for storing instructions and data for each process executing in a processing circuit. Processes access data using instructions with logical block addresses (LBAs), which are converted to addresses of physical memory locations accessible by the processing circuit. In this regard, LBAs are mapped to specific physical memory circuits. One type of memory used in electronic devices and computers is non-volatile FLASH memory (NVM), which retains data values stored therein even in the absence of a power supply. In a preferred embodiment, “NVM” herein refers to NAND-type FLASH memory, but other embodiments within the scope of the present disclosure are applicable to other types of NVM.

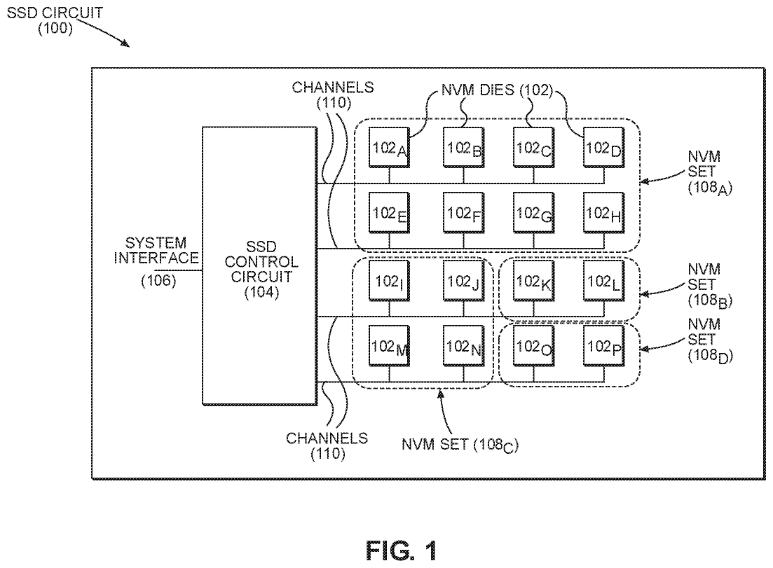

FIG. 1 is a schematic diagram of an exemplary SSD 100, also referred to herein as SSD circuit 100, according to the present disclosure. The SSD 100 is a NVM storage device in which data is stored in a plurality of NVM dies 102_{A}-102_{P} controlled by a SSD control circuit 104. The NVM dies 102_{A}-102_{P} are also referred to herein as NVM circuits 102_{A}-102_{P}, and collectively referred to herein as NVM dies 102. The SSD 100 may be coupled to a system including a processing circuit (not shown) at a system interface 106, such as a peripheral component interface (PCI) express (PCIe) or another processing system interface. The storage spaces of processes executing in the processing circuit are mapped to memory locations in the SSD 100. These storage spaces are referred to as NVM sets 108. In the example in FIG. 1, the SSD control circuit 104 is coupled to four channels 110. Each of the NVM dies 102 is also coupled to one of the channels 110. The NVM dies 102 communicate with the SSD control circuit 104 over the channels 110. In accordance with inventive aspects herein, the SSD control circuit 104 may be coupled to any number of channels 110 that are also coupled to NVM dies 102.

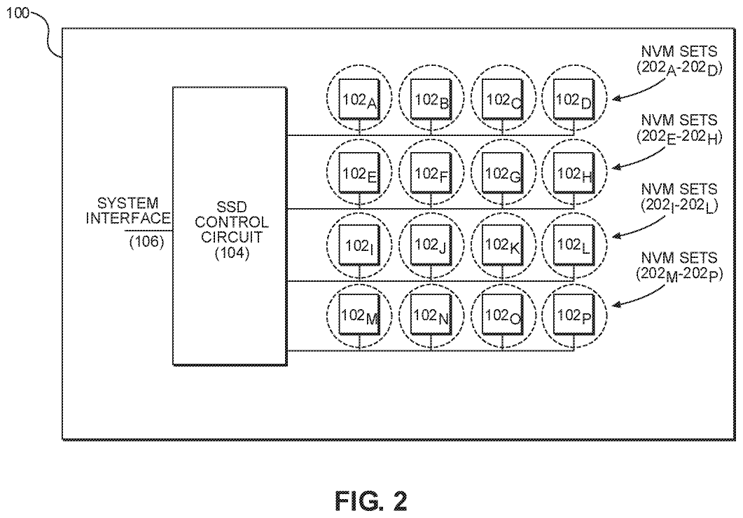

When a process in the processing circuit issues a memory request, also referred to herein as a memory access, operation, or instruction, to the SSD 100, the SSD control circuit 104 receives the request over the system interface 106, and generates a corresponding instruction on one or more of the channels 110 to access the NVM dies 102. FIG. 1 illustrates NVM sets 108_{A}-108_{D} mapped to storage locations in the SSD 100. As shown, NVM set 108_{A} is mapped to NVM dies 102_{A}-102_{H}. Thus, the storage space of NVM set 108_{A} has the capacity of eight (8) of the NVM dies 102. In one example, the storage capacity of the NVM dies 102 may be 512 giga-bytes (GB) each. As such, NVM set 108_{A} has a capacity of four (4) terra-bytes (TB) in this example. The NVM set 108_{B} is mapped to NVM dies 102_{I}, 102_{J}, 102_{M}, and 102_{N}. The NVM set 108_{C} is mapped to NVM dies 102_{K}, and 102_{L}. The NVM set 108_{D} is mapped to NVM dies 102_{O} and 102_{P}. Another example of a mapping configuration of NVM sets 108 to the NVM dies 102 of SSD 100 is shown in FIG. 2.

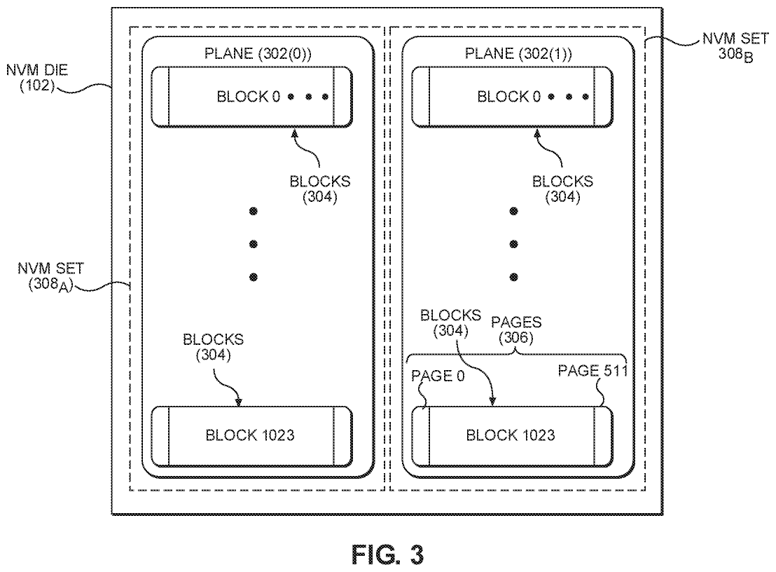

FIG. 2 is a schematic diagram of the SSD 100 in FIG. 1, with a different mapping configuration of NVM sets than FIG. 1, but the interconnection of physical components in FIG. 2 corresponds to FIG. 1. In FIG. 2, the NVM sets 202_{A}-202_{P} are mapped to the NVM dies 102_{A}-102_{P}, respectively. The entire capacity of each NVM die 102 is dedicated to one corresponding process. Thus, with NVM sets 202 mapped as shown in FIG. 2, a storage space of one NVM set 202 is equal to the entire storage capacity of a NVM die 102. However, one of the NVM sets 202 may never use the amount of storage available in one of the NVM dies 102. Further, as fabrication techniques improve, NVM die sizes continue to increase in capacity, while a NVM set 202 remains the same, so the portion of unused storage in the NVM die 102 becomes larger. Wasted storage space can unnecessarily increase the cost of an electronic device. Thus, as the NVM die 102 sizes increase, one considered solution is to map more than one NVM set 202 to the same NVM die 102. In other words, an NVM set 202 could be mapped to a subset of the NVM die 102, as explained in more detail with reference to FIG. 3.

FIG. 3 is a schematic diagram illustrating organization of NVM cells (not shown) in a NVM die 102. As shown in the example in FIG. 3, NVM cells in the NVM dies 102 are organized in planes 302(0) and 302(1), also referred to collectively as planes 302. Although the example in FIG. 3 includes only two planes 302, aspects disclosed herein are applicable to NVM dies 102 having two or more planes 302. Each of the planes 302 includes a plurality of memory blocks BLOCK 0 through BLOCK 1023 (i.e., 1024 memory blocks) referred to herein as blocks 304. The blocks 304 are each formed of pages PAGE 0 through PAGE 511 (i.e., 512 pages), referred to herein as pages 306, of NVM cells. In the example in FIG. 3, each of the planes 302 includes the blocks 304, each block 304 includes the pages 306, and each page 306 includes 16 kilobytes (KB) of memory for storing data and spare bytes for storing extra bits for purposes such as error correction codes (ECCs). The number of planes, number of blocks in each plane, and number of pages in each block in a NVM die 102 is a design choice and any NVM die 102 with a plurality of planes having any numbers of blocks and pages is within the scope of this disclosure.

To avoid having a large amount of storage capacity of the NVM dies 102, organized as shown in FIG. 3, be underutilized, one possible solution is to map a NVM set 308_{A} of a first process to the plane 302(0) and a NVM set 308_{B} of a second process to plane 302(1) of the NVM die 102. However, with such configuration, the first process and the second process both actually access the same physical device. Since each type of memory instruction (e.g., read, write (i.e., program), erase) has a corresponding completion time in the NVM dies 102, sequential execution of the memory instructions of the respective processes, in the absence of the inventive aspects disclosed herein, can cause conflicts between the processes, occasionally resulting in extended memory access latency. Consequently, it would be desirable to perform memory accesses to more than one plane 302 of an NVM die 102 at a time, to avoid such latencies.

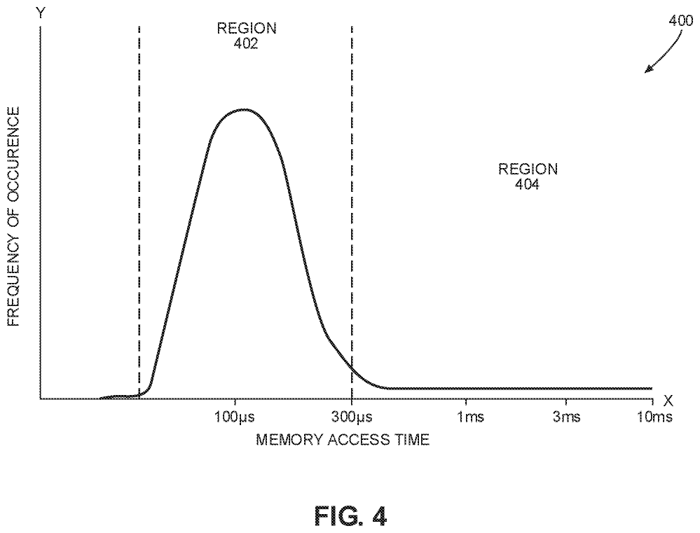

High voltage levels required to write to a page in a NVM die 102 can interfere with attempts to concurrently perform read or erase instructions in another plane of the NVM die 102. Thus, when a page 306 in one plane 302 of the NVM die 102 is in the process of completing a write instruction, neither a read instruction nor an erase instruction can occur in another plane 302. Additionally, in the absence of the present disclosure, there are address limitations on concurrent write instructions in respective planes of a single NVM die. Specifically, in the absence of inventive aspects disclosed herein, NVM dies do not concurrently write data to pages in different planes, where the addresses of the respective pages are fully independent of each other. Thus, in the absence of aspects disclosed herein, read, write, and erase instructions of a process having a NVM set mapped to one plane of a NVM die may execute sequentially after waiting for completion of instructions directed to another plane by another process. A later arriving memory instruction may not be able to concurrently execute, even if it is the same type of instruction. Thus, the process may experience long delays, depending on the type of instruction that must complete first. An example of such behavior is illustrated in FIG. 4.

FIG. 4 is a graphical representation (graph) 400 of memory access times of a NVM die organized as the NVM die 102 shown in FIG. 3, but in the absence of inventive aspects disclosed herein. In the graph 400 in FIG. 4, memory access time is plotted along the X axis and a frequency of occurrence of the memory access times is plotted along the Y axis. As shown in region 402 of FIG. 4, the most frequently occurring memory access times are within a window of duration having relatively low access time or latency. The example in FIG. 4 indicates memory access times of a NAND type NVM with memory access times of approximately 100 microseconds (μs) occurring with greatest frequency, and a majority of the memory access times falling in a range up to 300 μs. Memory access times can vary substantially from one NVM to another, and the times in FIG. 4 are just one example. Region 404 of FIG. 4 includes longer memory access times that occur with much lower frequency. The occasional long latencies of memory accesses in region 404, which are referred to as tail latencies, can cause noticeable delays in system performance. Thus, in the absence of inventive aspects disclosed herein, the considered solution trades a reduction of unused memory for system performance.

The NVM dies 102 of the SSD 100 in FIG. 1 overcome such tradeoffs. In particular, the NVM dies 102 disclosed herein are capable of concurrent execution of write instructions to different planes 302 within one of the NVM dies 102, where the addresses of the pages written in each plane are independent of each other. In yet another inventive aspect, rather than issuing instructions in the order they are received in the SSD 100, the SSD control circuit 104 disclosed herein intelligently controls generation of memory instructions on the channels 110 by implementing instruction-type time slices in which only instructions corresponding to a current instruction-type time slice are generated on the channel 110. Since instructions of the same type to different planes are completed concurrently in the NVM dies 102 disclosed herein, the implementation of instruction-type time slices optimizes performance of the SSD 100 in which multiple NVM sets 108 are mapped to a single NVM die 102.

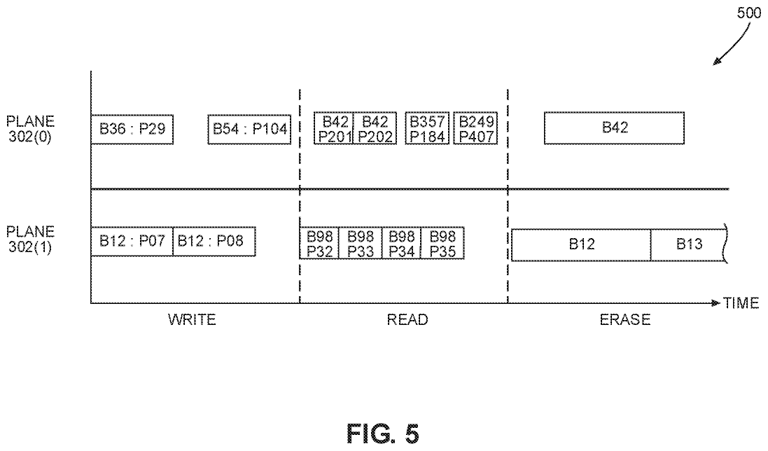

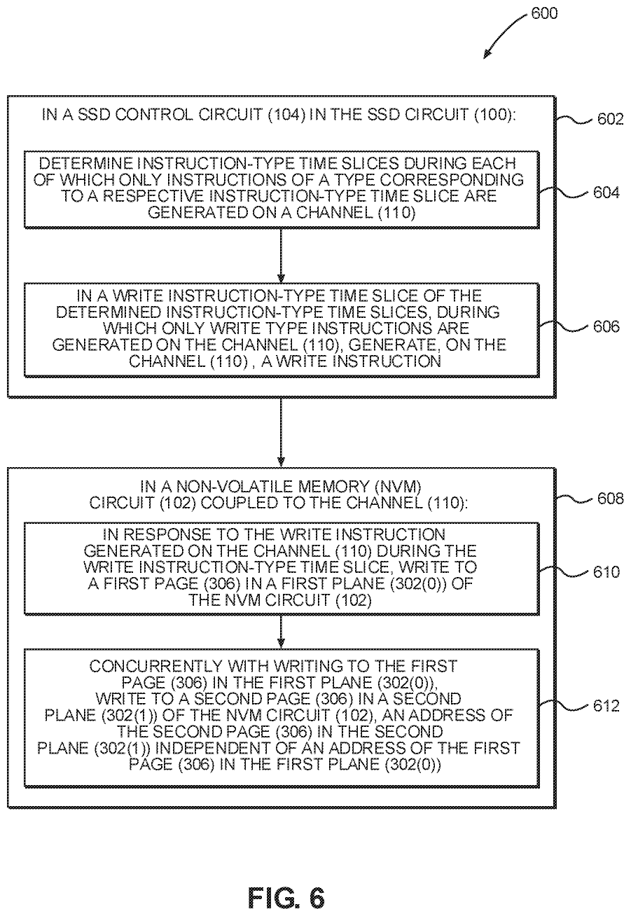

FIG. 5 is a timing diagram 500 illustrating instruction-type time slices on one channel 110 in the SSD circuit 100. The timing diagram 500 illustrates the timing of instructions in the SSD 100 according to a process 600 in FIG. 6. References are made to the process 600 in the description of FIG. 5. Instruction-type time slices write, read, and erase shown in FIG. 5 indicate periods of time during which only instructions of a type corresponding to the instruction-type time slice are generated on a channel 110. For example, during the write instruction-type time slice, only write instructions are generated on the channel 110. During the read instruction-type time slice shown in FIG. 5, only read instructions are generated on the channel 110. During the erase instruction-type time slice the SSD control circuit 104 only generates erase instructions on the channel 110. The order and duration of the time slices shown in FIG. 5 are examples only. The instruction-type time slices may be in any order as determined by methods described below. The durations of the instruction-type time slices shown in FIG. 5 are not to scale, and actual time slices may have longer or shorter relative durations than shown in FIG. 5. Thus, one or more instructions of the corresponding type(s) may be generated by the SSD control circuit 104 and executed in the NVM dies 102 in each instruction-type time slice.

In the process 600, the SSD control circuit 104 (block 602) determines the instruction-type time slices, during each of which only instructions of a type corresponding to a respective instruction-type time slice are generated on the channel 110 (block 604). The SSD control circuit 104 determines the instruction-type time slices and their respective durations by one or more methods, such as the following. In one example, the SSD control circuit 104 sets a schedule for the order and duration of each type of instruction-type time slice based on a history of memory accesses. In another example, the order and duration of instruction-type time slices may be programmed based on testing or statistical data. In another example, the SSD control circuit 104 dynamically determines a next instruction-type time slice and duration based on current outstanding memory instructions. For example, the SSD control circuit 104 may accumulate instructions (e.g., in a buffer) received on the system interface 106 while waiting for the NVM dies 102 to complete previous memory instructions. Depending on a number, type, and other factors (e.g., priority indication) of pending instructions, the SSD control circuit 104 may determine a next instruction-type time slice and duration of such time slice.

The process 600 further includes, in the write instruction-type time slice, which is among the determined instruction-type time slices, during which only write type instructions are generated on the channel 110, the SSD control circuit 104 generates, on the channel 110, a write instruction (block 606). In an example shown in FIG. 5, the SSD control circuit 104 generates a write instruction to write to pages in each of plane 302(0) and plane 302(1). In this example, one instruction includes page addresses and data for writing to PAGE 29 of BLOCK 36 in plane 302(0) and PAGE 07 of BLOCK 12 in plane 302(1). In this example, the write instruction also indicates the second page in the second plane.

The NVM circuit 102 in FIG. 1 is coupled to the channel 110. As discussed above with regard to FIG. 3, the NVM circuit 102 includes a first plane 302(0) including a first plurality of blocks 304 each formed of pages 306, and a second plane 302(1) including a second plurality of blocks 304 each formed of pages 306, and the second plurality of blocks 304 is separate from the first plurality of blocks 304. The process 600 further includes, in the NVM circuit 102 (block 608) coupled to the channel 110, in response to the write instruction generated on the channel 110 indicating a first page 306 (e.g., PAGE 29 of BLOCK 36) in the first plane 302(0), the NVM circuit 102 writes to the first page 306 in the first plane 302(0) (i.e., PAGE 29 of BLOCK 36 in plane 302(0)) (block 610). The process 600 further includes, concurrently with writing to the first page 306 in the first plane 302(0), the NVM circuit 102 writes to a second page 306 (e.g., PAGE 07 of BLOCK 12) in the second plane 302(1), wherein an address of the second page 306 (i.e., PAGE 07 of BLOCK 12) in the second plane 302(1) is independent of an address of the first page 306 (i.e., PAGE 29 of BLOCK 54) in the first plane 302(0) (block 612). In this example, since the write instruction indicates the second page 306 to be written, the NVM circuit 102 writes to the second page 306 in the second plane 302(1) in response to the write instruction. The write instruction in this example includes first data (not shown) to be written to the first page 306 of the first plane 302(0) and second data (not shown) to be written to the second page 306 of the second plane 302(1). Thus, in response to the write instruction generated on the channel 110, the NVM circuit 102 writes to the first data in the first page 306 in the first plane 302(0). The NVM circuit 102 also writes to the second data in the second page 306 in the second plane 302(1), the second data being different than the first data.

In another example, the SSD control circuit 104, during the write instruction-type time slice, generates a first instruction to write to a first page 306 in a first plane 302(1) and generates a second write instruction indicating a second page 306 in a second plane 302(0). In this example, the SSD control circuit 104 generates the first instruction to write to the first page 306 (e.g., PAGE 08 of BLOCK 12) of the first plane 302(1) and the second write instruction to write to the second page 306 (e.g., PAGE 104 of BLOCK 54) of the second plane 302(0). In this example, the NVM circuit 102 writes to the second page 306 in the second plane 302(0) in response to the second write instruction. The writing of PAGE 08 of BLOCK 12 of plane 302(1) begins first, and the writing of PAGE 104 of BLOCK 54 of plane 302(0) begins before writing of PAGE 08 of BLOCK 12 of plane 302(1) is completed. Thus, even though the write instructions were generated sequentially on the channel 110, the times for the NVM circuit to complete writing to the respective pages 306 of the planes 302 can overlap, or occur concurrently, reducing a memory access time for the second write instruction. Concurrent execution of the write instructions is possible because there is no dependency between the address or location of a page 306 written in a first plane 302 and the address of a page 306 written concurrently in a second plane 302 in the NVM circuit 102.

Following the write instruction-type time slice in FIG. 5 are a read instruction-type time slice and an erase instruction-type time slice. As with the write instructions, the illustration in FIG. 5 shows that the planes 302 can concurrently read data in pages 306 of blocks 304 that are independent of each other. Thus, the SSD control circuit 104, in a read instruction-type time slice during which only read instructions are generated on the channel 110, generates one or more read instructions on the channel 110. In the read instruction-type time slice, PAGE 32 through PAGE of BLOCK 98 of plane 302(1) are read in consecutive order while various pages of blocks 304 in plane 302(0) are also read. Specifically, PAGES 201 and 202 of BLOCK 42, PAGE 184 of BLOCK 357, and PAGE 407 of BLOCK 249 of plane 302(0) are read during the read instruction-type time slice in FIG. 5. In response to the read instruction generated on the channel 110, the NVM circuit 102 reads data stored at a first read address in a first plane 302(0), for example, and, concurrently with reading data stored at the first address in the first plane 302(0), reads data stored at a second read address in the second plane 302(1), for example, where the second read address in the second plane 302(1) is independent of the first read address in the first plane 302(0). In some examples, the SSD control circuit 104, during a read instruction-type time slice, may generate a second read instruction indicating the second read address in the second plane 302(1). In response to the second read instruction, the NVM circuit 102 reads data stored at the second read address in the second plane 302(1).

FIG. 5 also illustrates erasing data stored in BLOCK 42 in plane 302(0) concurrently with erasing data stored in BLOCK 12 and BLOCK 13 of plane 302(1). Thus, the SSD control circuit 104, in an erase instruction-type time slice during which only erase instructions are generated on the channel 110, generates one or more erase instructions on the channel 110. In response to the erase instruction generated on the channel 110, the NVM circuit 102 erases data stored in a first block 304 in the first plane 302(0) and, concurrently with erasing data stored in the first block in the first plane 302(0), erases data stored in a second block 304 in the second plane 302(1), for example, where an address of the second block 304 in the second plane 302(1) is independent of an address of the first block 304 in the first plane 302(0). In some examples, the SSD control circuit 104, during an erase instruction-type time slice, may generate a second erase instruction indicating the second block 304 in the second plane 302(1). In response to the second erase instruction, the NVM circuit 102 erases data stored in the second block 304 in the second plane 302(1).

In another example, not shown, the SSD control circuit 104 may determine only two instruction-type time slices in the SSD 100 for the NVM circuits 102 capable of reading data in a page 306 of a first plane 302 concurrently with erasing data in a block 304 of another plane 302. Thus, the SSD control circuit 104 would determine a read instruction-type time slice and a read-erase instruction-type time slice in the SSD 100 by methods similar to those discussed above for determining a write, read, or erase instruction-type time slice described above. In this example, the SSD control circuit 104, in a read-erase instruction-type time slice, during which only read instructions and erase instructions are generated on the channel 110, generates a read instruction and an erase instruction on the channel 110. The NVM circuit 102, in response to the read instruction generated on the channel 110, reads data stored at a first read address in a first plane 302(0), for example, and in response to the erase instruction, erases data stored in a block 304 in the second plane 302(1) concurrently with reading the data stored at the first read address in the first plane 302(0).

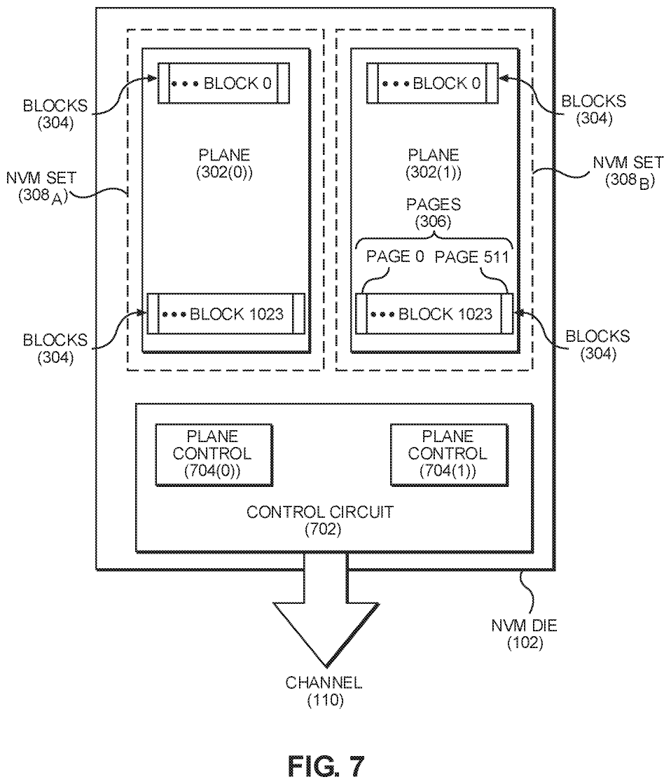

FIG. 7 is a schematic diagram of a NVM circuit 102 in the SSD 100 in FIGS. 1 and 2 with memory organization as illustrated in FIG. 3. The NVM circuit 102 includes a first plane 302(0) including a first plurality of blocks 304 each formed of pages 306, and a second plane 302(1) including a second plurality of blocks each formed of pages 306. The second plurality of blocks in the second plane 302(1) is separate and independent from the first plurality of blocks in the first plane 302(0). As previously discussed, the NVM die 102 is coupled to a channel 110. The NVM circuit 102 includes a control circuit 702 controlling bidirectional communication with the SSD control circuit 104 over the channel 110. For example, instructions generated on the channel 110 are received in the NVM circuit 102 by the control circuit 702. The control circuit 702 also receives data from the SSD control circuit 104 for writing to pages 306 in the NVM circuit 102. The control circuit 702 also transmits data to the SSD control circuit 104 over the channel 110 in response to read instructions received on the channel 110 in a read time slice.

In one example, the control circuit 702 receives a first instruction indicating a first page 306 in the first plane 302(0). In response to receiving the first instruction, the control circuit 702 writes to the first page 306 in the first plane 302(0), for example. Concurrently with writing to the first page 306 in the first plane 302(0), the control circuit 702 writes to a second page 306 in the second plane 302(1) of the NVM circuit 102, such that an address of the second page 306 of the second plane 302(1) is independent of an address of the first page 306 in the first plane 302(0). In the NVM circuit 102, writing to the first page 306 in the first plane 302(0) includes storing first data in the first page 306 in the first plane 302(0), and writing to the second page 306 in the second plane 302(0) includes storing second data in the second page 306 in the second plane 302(1), where the first data is different from the second data.

In some examples, the control circuit 702 receives the first instruction indicating the second page 306 in the second plane 302(1), and writes to the second page 306 in the second plane 302(1) in response to the first instruction. In some examples, the control circuit 702 receives a second instruction indicating the second page 306 in the second plane 302(1) and writes to the second page 306 in the second plane 302(1) in response to the second instruction.

The control circuit 702 includes plane control 704(0) and plane control 704(1) to independently control memory accesses to planes 302(0) and 302(1). Memory instructions received on the channel 110 may be directed by the control circuit 702 to the appropriate destination plane control 704(0) or 704(1) based on the plane 302 of a page 306 or block 304 to be accessed by the memory instruction. Alternatively, both of plane controls 704(0) and 704(1) may receive each instruction and make a determination of whether a page 306 or block 304 addressed by a memory instruction is contained in the corresponding plane 302(0) or 302(1). The control circuit 702 employs plane controls 704(0) and 704(1) to concurrently execute memory access instructions to independent addresses (pages 306 and/or blocks 304) within planes 302(0) and 302(1) during corresponding instruction-type time slices.

In other examples, the control circuit 702 receives a first erase instruction indicating a first block 304 in a first plane 302(0), for example. In response to receiving the first erase instruction, the control circuit 702 erases data stored in the first block 304 of the first plane 302(0). Concurrently with erasing the first data stored in the first block 304 in the first plane 302(0), the control circuit 702 erases second data stored in a second block 304 of a second plane 302(1), for example. In additional examples, the control circuit 702 receives a first read instruction including a first address in the first plane 302(0). In response to receiving the first read instruction, the control circuit 702 reads first addressed data stored in the first plane 302(0), wherein the first addressed data is indicated by the first address. Concurrently with reading the first addressed data, the control circuit 702 reads second addressed data indicated by a second address different than the first address. The second address may be received in the first read instruction or a second read instruction.

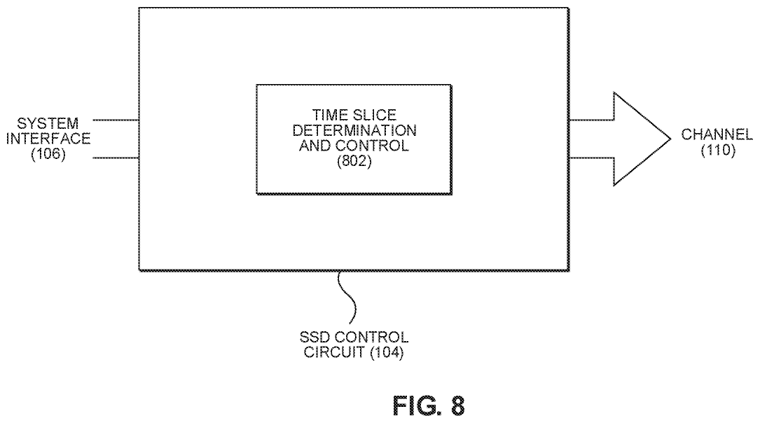

FIG. 8 is a schematic diagram of the SSD control circuit 104 coupled to the system interface 106 and at least one channel 110. As shown, the SSD control circuit 104 in the SSD circuit 100 includes a time slice determination and control 802 for determining instruction-type time slices and their durations by one of the methods described above (e.g., memory access history, programming, dynamic determination). The time slice determination and control 802 also controls generation of instructions on the channel 110 corresponding to the determined instruction-type time slice. The SSD control circuit 104 determines instruction-type time slices during each of which only instructions of a type corresponding to a respective instruction-type time slice are generated on the channel 110. During a write instruction-type time slice among the determined instruction-type time slices, during which only write type instructions are generated on the channel 110, the SSD control circuit 104 generates, on the channel 110, a write instruction indicating a first page 306 in a first plane 302(0), for example, of the NVM circuit 102. The generated write type instruction indicates a second page 306 of a second plane 302(1) of the NVM circuit 102, and an address of the first page 306 is independent of an address of the second page 306. Although only the time slice determination and control 802 are shown in the SSD control circuit 104 in FIG. 8, it is understood that the SSD control circuit 104 includes other circuits for performing many other functions (not shown) required for operation of the SSD circuit 100.

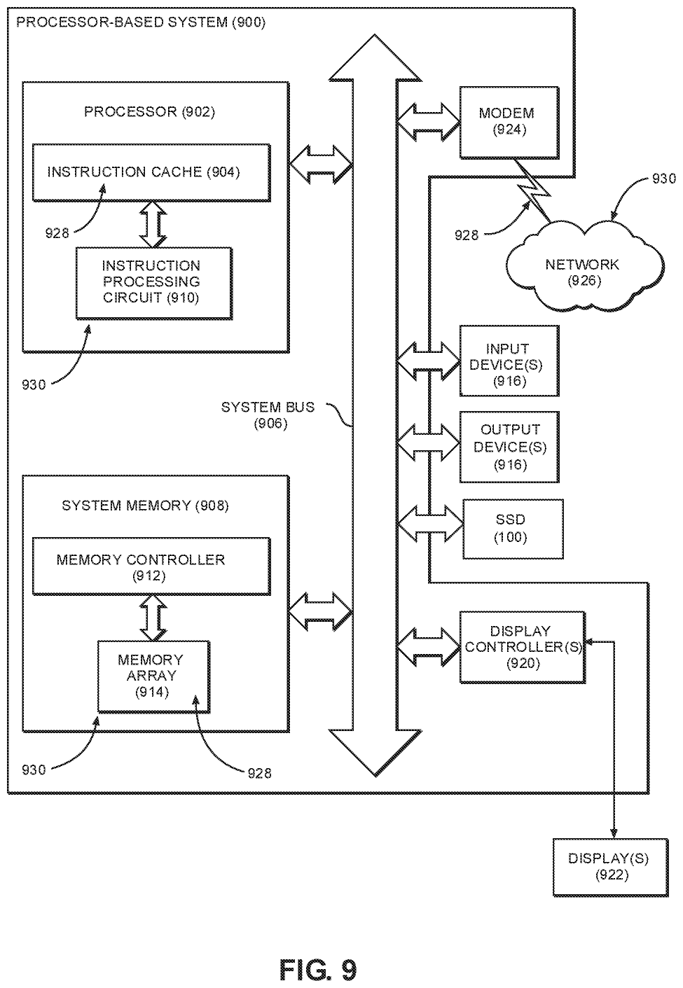

FIG. 9 is a block diagram of an exemplary processor-based system 900 that includes a processor 902 (e.g., a microprocessor) that includes an instruction processing circuit 910. The processor-based system 900 may be a circuit or circuits included in an electronic board card, such as a printed circuit board (PCB), a server, a personal computer, a desktop computer, a laptop computer, a personal digital assistant (PDA), a computing pad, a mobile device, or any other device, and may represent, for example, a server, or a user's computer. In this example, the processor-based system 900 includes the processor 902. The processor 902 represents one or more general-purpose processing circuits, such as a microprocessor, central processing unit, or the like. The processor 902 is configured to execute processing logic in instructions for performing the operations and steps discussed herein.

The processor 902 and system memory 908 are coupled to a system bus 906 that can intercouple peripheral devices included in the processor-based system 900. As is well known, the processor 902 communicates with these other devices by exchanging address, control, and data information over the system bus 906. For example, the processor 902 can communicate bus transaction requests to a memory controller 912 in the system memory 908 as an example of a slave device. Although not illustrated in FIG. 9, multiple system buses 906 could be provided, wherein each system bus constitutes a different fabric. In this example, the memory controller 912 is configured to provide memory access requests to a memory array 914 in the system memory 908. The memory array 914 is comprised of an array of storage bit cells for storing data. The system memory 908 may be a read-only memory (ROM), flash memory, dynamic random access memory (DRAM), such as synchronous DRAM (SDRAM), etc., and a static memory (e.g., flash memory, static random access memory (SRAM), etc.), as non-limiting examples. The processor-based system 900 includes a SSD circuit 100 including the SSD control circuit 104 determining instruction-type time slices in which specific types of instructions are generated, and NVM dies 102 capable of concurrently accessing independent memory locations in respective planes. The SSD circuit 100 may be included in the system memory 908 or coupled to the system bus 906, as shown in FIG. 9.

Other devices can be connected to the system bus 906. As illustrated in FIG. 9, these devices can include the system memory 908, one or more input devices 916, one or more output devices 918, a modem 924, and one or more display controllers 920, as examples. The input device(s) 916 can include any type of input device, including, but not limited to, input keys, switches, voice processors, etc. The output device(s) 918 can include any type of output device, including, but not limited to, audio, video, other visual indicators, etc. The modem 924 can be any device configured to allow exchange of data to and from a network 926. The network 926 can be any type of network, including, but not limited to, a wired or wireless network, a private or public network, a local area network (LAN), a wireless local area network (WLAN), a wide area network (WAN), a BLUETOOTH™ network, and the Internet. The modem 924 can be configured to support any type of communications protocol desired. The processor 902 may also be configured to access the display controller(s) 920 over the system bus 906 to control information sent to one or more displays 922. The display(s) 922 can include any type of display, including, but not limited to, a cathode ray tube (CRT), a liquid crystal display (LCD), a plasma display, etc.

The processor-based system 900 in FIG. 9 may include a set of instructions 928 to be executed by the processor 902 for any application desired according to the instructions. The instructions 928 may be stored in the system memory 908, and/or instruction cache 904 of the processor 902, as examples of a non-transitory computer-readable medium 930. The instructions 928 may also reside, completely or at least partially, within the system memory 908 and/or within the processor 902 during their execution. The instructions 928 may further be transmitted or received over the network 926 via the modem 924, such that the network 926 includes computer-readable medium 930.

While the computer-readable medium 930 is shown in an exemplary embodiment to be a single medium, the term “computer-readable medium” should be taken to include a single medium or multiple media (e.g., a centralized or distributed database, and/or associated caches and servers) that stores the one or more sets of instructions. The term “computer-readable medium” shall also be taken to include any medium that is capable of storing, encoding, or carrying a set of instructions for execution by the processing device and that causes the processing device to perform any one or more of the methodologies of the embodiments disclosed herein. The term “computer-readable medium” shall accordingly be taken to include, but not be limited to, solid-state memories, optical medium, and magnetic medium.

The embodiments disclosed herein include various steps. The steps of the embodiments disclosed herein may be formed by hardware components or may be embodied in machine-executable instructions, which may be used to cause a general-purpose or special-purpose processor programmed with the instructions to perform the steps. Alternatively, the steps may be performed by a combination of hardware and software.

The embodiments disclosed herein may be provided as a computer program product, or software, that may include a machine-readable medium (or computer-readable medium) having stored thereon instructions, which may be used to program a computer system (or other electronic devices) to perform a process according to the embodiments disclosed herein. A machine-readable medium includes any mechanism for storing or transmitting information in a form readable by a machine (e.g., a computer). For example, a machine-readable medium includes: a machine-readable storage medium (e.g., ROM, random access memory (“RAM”), a magnetic disk storage medium, an optical storage medium, flash memory devices, etc.); and the like.

Unless specifically stated otherwise and as apparent from the previous discussion, it is appreciated that throughout the description, discussions utilizing terms such as “processing,” “computing,” “determining,” “displaying,” or the like, refer to the action and processes of a computer system, or similar electronic computing device, that manipulates and transforms data and memories represented as physical (electronic) quantities within the computer system's registers into other data similarly represented as physical quantities within the computer system memories or registers or other such information storage, transmission, or display devices.

The algorithms and displays presented herein are not inherently related to any particular computer or other apparatus. Various systems may be used with programs in accordance with the teachings herein, or it may prove convenient to construct more specialized apparatuses to perform the required method steps. The required structure for a variety of these systems will appear from the description above. In addition, the embodiments described herein are not described with reference to any particular programming language. It will be appreciated that a variety of programming languages may be used to implement the teachings of the embodiments as described herein.

Those of skill in the art will further appreciate that the various illustrative logical blocks, modules, circuits, and algorithms described in connection with the embodiments disclosed herein may be implemented as electronic hardware, instructions stored in memory or in another computer-readable medium and executed by a processor or other processing device, or combinations of both. The components of the distributed antenna systems described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends on the particular application, design choices, and/or design constraints imposed on the overall system. Skilled artisans may implement the described functionality in varying ways for each particular application, but such implementation decisions should not be interpreted as causing a departure from the scope of the present embodiments.

The various illustrative logical blocks, modules, and circuits described in connection with the embodiments disclosed herein may be implemented or performed with a processor, a Digital Signal Processor (DSP), an Application Specific Integrated Circuit (ASIC), a Field Programmable Gate Array (FPGA), or other programmable logic device, a discrete gate or transistor logic, discrete hardware components, or any combination thereof designed to perform the functions described herein. Furthermore, a controller may be a processor. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The embodiments disclosed herein may be embodied in hardware and in instructions that are stored in hardware, and may reside, for example, in RAM, flash memory, ROM, Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined. Those of skill in the art will also understand that information and signals may be represented using any of a variety of technologies and techniques. For example, data, instructions, commands, information, signals, bits, symbols, and chips, that may be references throughout the above description, may be represented by voltages, currents, electromagnetic waves, magnetic fields, or particles, optical fields or particles, or any combination thereof.

Unless otherwise expressly stated, it is in no way intended that any method set forth herein be construed as requiring that its steps be performed in a specific order. Accordingly, where a method claim does not actually recite an order to be followed by its steps, or it is not otherwise specifically stated in the claims or descriptions that the steps are to be limited to a specific order, it is in no way intended that any particular order be inferred.

It will be apparent to those skilled in the art that various modifications and variations can be made without departing from the spirit or scope of the invention. Since modifications, combinations, sub-combinations and variations of the disclosed embodiments incorporating the spirit and substance of the invention may occur to persons skilled in the art, the invention should be construed to include everything within the scope of the appended claims and their equivalents.

1. A solid-state device (SSD) circuit, comprising:
a SSD control circuit coupled to a channel, the SSD control circuit configured to:
determine instruction-type time slices during each of which only instructions of a type corresponding to a respective instruction-type time slice are generated on the channel; and
in a write instruction-type time slice among the determined instruction-type time slices, during which only write type instructions are generated on the channel, generate, on the channel, a write instruction; and
a non-volatile memory (NVM) circuit coupled to the channel, the NVM circuit comprising:
a first plane comprising a first plurality of blocks each formed of pages; and
a second plane comprising a second plurality of blocks each formed of pages;
wherein the NVM circuit is configured to:
in response to the write instruction generated on the channel indicating a first page in the first plane, write to the first page in the first plane; and
concurrently with writing to the first page in the first plane, write to a second page in the second plane, an address of the second page in the second plane independent of an address of the first page in the first plane.

2. The SSD circuit of claim 1, wherein:
the SSD control circuit is further configured to, during the write instruction-type time slice, generate a second write instruction indicating the second page in the second plane; and
the NVM circuit is further configured to write to the second page in the second plane in response to the second write instruction.

3. The SSD circuit of claim 1, wherein:
the write instruction indicates the second page in the second plane; and
the NVM circuit is further configured to write to the second page in the second plane in response to the write instruction.

4. The SSD circuit of claim 1, wherein the NVM circuit is further configured to:
in response to the write instruction generated on the channel, write first data in the first page in the first plane; and
write second data in the second page in the second plane, the second data different than the first data.

5. The SSD circuit of claim 1, wherein the second plurality of blocks is separate from the first plurality of blocks.

6. The SSD circuit of claim 1, wherein:
the SSD control circuit is further configured to:
in a read instruction-type time slice, during which only read instructions are generated on the channel, generate, on the channel, a read instruction; and
in an erase instruction-type time slice, during which only erase instructions are generated on the channel, generate, on the channel, an erase instruction; and
the NVM circuit is further configured to:
in response to the read instruction generated on the channel, read data stored at a first read address in the first plane;
concurrently with reading the data stored at the first read address in the first plane, read data stored at a second read address in the second plane, the second read address independent of the first read address in the first plane;
in response to the erase instruction generated on the channel, erase data stored in a first block of the first plurality of blocks in the first plane; and
concurrently with erasing the data stored in the first block of the first plurality of blocks in the first plane, erase data stored in a second block of the second plurality of blocks in the second plane, an address of the second block independent of an address of the first block.

7. The SSD circuit of claim 6, wherein:
the SSD control circuit is further configured to, during the read instruction-type time slice, generate a second read instruction indicating the second read address in the second plane;
the NVM circuit is further configured to read the data stored at the second read address in the second plane in response to the second read instruction;
the SSD control circuit is further configured to, during the erase instruction-type time slice, generate a second erase instruction indicating the second block in the second plane; and
the NVM circuit is further configured to erase the data stored in the second block in the second plane in response to the second erase instruction.

8. The SSD circuit of claim 1, wherein:
the SSD control circuit is further configured to:
in a read-erase instruction-type time slice, during which only read instructions and erase instructions are generated on the channel, generate, on the channel, a read instruction and an erase instruction; and
the NVM circuit is further configured to:
in response to the read instruction generated on the channel, read data stored at a first read address in the first plane; and
in response to the erase instruction, erase data stored in a block of the second plane concurrently with reading the data stored at the first read address in the first plane.

9-15. (canceled)

16. A solid-state device (SSD) control circuit, configured to:
determine instruction-type time slices during each of which only instructions of a type corresponding to a respective instruction-type time slice are generated on a channel; and
during a write instruction-type time slice of the determined instruction-type time slices, during which only write type instructions are generated on the channel, generate, on the channel, a write instruction indicating a first page in a plane of a non-volatile memory (NVM) circuit, and indicating a second page of a second plane of the NVM circuit, an address of the first page independent of an address of the second page.

17. A method performed in a solid-state device (SSD) circuit, the method comprising:
in a SSD control circuit in the SSD circuit:
determining instruction-type time slices during each of which only instructions of a type corresponding to a respective instruction-type time slice are generated on a channel; and
during a write instruction-type time slice of the determined instruction-type time slices, during which only write type instructions are generated on the channel, generating, on the channel, a write instruction; and
in a non-volatile memory (NVM) circuit coupled to the channel:
in response to the write instruction generated on the channel during the write instruction-type time slice, writing to a first page in a first plane of the NVM circuit; and
concurrently with writing to the first page in the first plane, writing to a second page in a second plane of the NVM circuit, an address of the second page in the second plane independent of an address of the first page in the first plane.

18. The method of claim 17, further comprising:
in the SSD control circuit, generating, on the channel, a second instruction indicating the second page in the second plane; and
in the NVM circuit, writing to the second page in the second plane in response to the second instruction.

19. The method of claim 17, wherein the write instruction further identifies the second page in the second plane.

20. The method of claim 17, wherein:
writing to the first page in the first plane of the NVM circuit comprises storing first data in the first page in the first plane of the NVM circuit; and
writing to the second page in the second plane of the NVM circuit comprises storing second data in the second page of the second plane of the NVM circuit.
